(19) United States
(12) Patent Application Publication
(10) Pub. No.: US 2005/0093639 A1
(43) Pub. Date: May 5, 2005

(54) Switching circuit and voltage-controlled oscillator including the same

(76) Inventor: Gojin Arakawa, Yokohama (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/952,447

(22) Filed: Sep. 29, 2004

(30) Foreign Application Priority Data
Sep. 30, 2003 (JP) 2003-341873

(51) Int. Cl. H03B 1/00

(52) U.S. Cl. 331/185

(57) ABSTRACT

A voltage controlled oscillator and a switching circuit therein are capable of surely disabling the unselected circuit. In the case where a switching voltage is low, a first PNP transistor is turned on, and a voltage is applied to a first circuit connecting to the collector of the first PNP transistor. A second PNP transistor is then turned off, and no voltage is applied to a second circuit connecting the collector of the second PNP transistor. In contrast, in the case where the switching voltage is high, the first PNP transistor is turned off, and voltage is not applied to the first circuit. The second PNP transistor is turned on, and a voltage is applied to the second circuit.

### BACKGROUND OF THE INVENTION

1. Field of the Invention

This invention generally relates to a switching circuit and a voltage controlled oscillator including the switching circuit, and more particularly, to a voltage controlled oscillator and a switching circuit included therein that are capable of switching output frequencies.

2. Description of the Related Art

Voltage controlled oscillators capable of switching the output frequencies have been proposed, as disclosed in Japanese Patent Application Publication No. 8(1996)-256078. The voltage controlled oscillator disclosed in the above publication is shown in FIG. 1.

Referring to FIG. 1, a voltage controlled oscillator 900 includes two voltage controlled oscillation circuits 910a and 910b, and a switching circuit 920. The switching circuit 920 selectively outputs an oscillation signal inputted from one of the two voltage controlled oscillation circuits 910a and 910b.

Specifically, the two voltage controlled oscillation circuits 910a and 910b oscillate in different frequency ranges based on control voltages respectively applied thereto. The oscillation signal from the voltage controlled oscillation circuit 910a is applied to a terminal 921a of the switching circuit 920. The oscillation signal from the voltage controlled oscillation circuit 910b is applied to a terminal 921b of the switching circuit 920. A switching voltage Vs is applied to the switching circuit 920, and then the oscillation signal applied to one of the terminals (921a or 921b) is selectively outputted.

It is to be noted that multiple voltage controlled oscillation circuits are operating simultaneously. Therefore, the oscillation signal outputted from one of the voltage controlled oscillation circuits affects the other voltage controlled oscillation circuit. It is thus difficult to control the oscillation frequency accurately.

Also, there is the problem in that a large amount of power is consumed because the voltage controlled oscillation circuit in an unselected state is also operating. This problem is fatal for electric devices, particularly those required to have lower power consumption such as cellular phones.

### SUMMARY OF THE INVENTION

The present invention has been made in view of the above circumstances and provides a switching circuit and a voltage controlled oscillator equipped with the switching circuit in which a circuit in the unselected state can surely be disabled.

According to an aspect of the present invention, a switching circuit including a first PNP transistor having a collector output switched on and off based on a switching voltage applied to a base, and a second PNP transistor having a collector output opposite to the collector output of the first PNP transistor, first and second circuits respectively coupled with the first and second PNP transistors being selectively operated in accordance with the collector outputs of the first and second PNP transistors. It is thus possible to control the enabled/disabled state of the first and second circuits respectively coupled with the first and second PNP transistors being selectively operated in accordance with the collector outputs of the first and second PNP transistors. It is also possible to keep the unselected circuit unoperated or disabled. The switching voltage is applied to the base of the first PNP transistor, which can prevent a large amount of current from flowing in an input terminal of the switching voltage. In the case where one PNP transistor is turned on, the other transistor can be turned off. In addition to a reduction in power consumption, the power consumed in each circuit can be controlled separately. Thus, circuit design can be facilitated.

According to another aspect of the present invention, a voltage controlled oscillator including a first voltage controlled oscillation circuit, a second voltage controlled oscillation circuit, and a switch selectively operates the first and second voltage controlled oscillation circuits, and the switch includes a first PNP transistor having a collector output switched on and off based on a switching voltage applied to a base, and a second PNP transistor having a collector output opposite to the collector output of the first PNP transistor, and the first and second voltage controlled oscillation circuits are selectively operated in accordance with the collector outputs of the first and second PNP transistors. In accordance with the state of the switching voltage, it is thus possible to control the enabled/disabled state of the first and second voltage controlled oscillation circuits that are respectively connected to the collectors of the first and second PNP transistors. The switching voltage is applied to the base of the first PNP transistor, and it is also possible to prevent a large amount of current from flowing in the input terminal of the switching voltage. Further, in the case where one PNP transistor is turned on, the other PNP transistor can be turned off. In addition to the reduction in power consumed by each voltage controlled oscillation circuit, the power consumed in each circuit can be controlled separately. Thus, circuit design can be facilitated.

According to yet another aspect of the present invention, a voltage controlled oscillator including two voltage controlled oscillation circuits that respectively oscillate in two different frequency ranges, and a switching circuit that selects one of the two voltage controlled oscillation circuits, and the switching circuit includes two PNP transistors respectively associated with the two voltage controlled oscillation circuits. Thus, the enabled/disabled state of each voltage controlled oscillation circuit can surely be controlled by on/off state of the corresponding PNP transistor. It is possible to disable the unselected voltage controlled oscillation circuit. The switching voltage is applied to the base of the first PNP transistor, and it is possible to prevent a large amount of current from flowing in the input terminal of the switching voltage. Further, in the case where one PNP transistor is turned on, the other PNP transistor can be turned off. In addition to the reduction in power consumed by each voltage controlled oscillation circuit, the power consumed in each circuit can be controlled separately. Thus, circuit design can be facilitated.

### BRIEF DESCRIPTION OF THE DRAWINGS

Preferred embodiments of the present invention will be described in detail based on the following figures, wherein:

FIG. 1 is a block diagram showing a voltage controlled oscillator 900 in the conventional technology;

FIG. 2 shows a circuit diagram of a voltage controlled oscillator 10 in a first reference example of a first embodiment;

FIG. 3 shows a circuit diagram of a voltage controlled oscillator 20 in a second reference example of the first embodiment; and

FIG. 4 shows a circuit diagram of a voltage controlled oscillator 30 in the first embodiment.

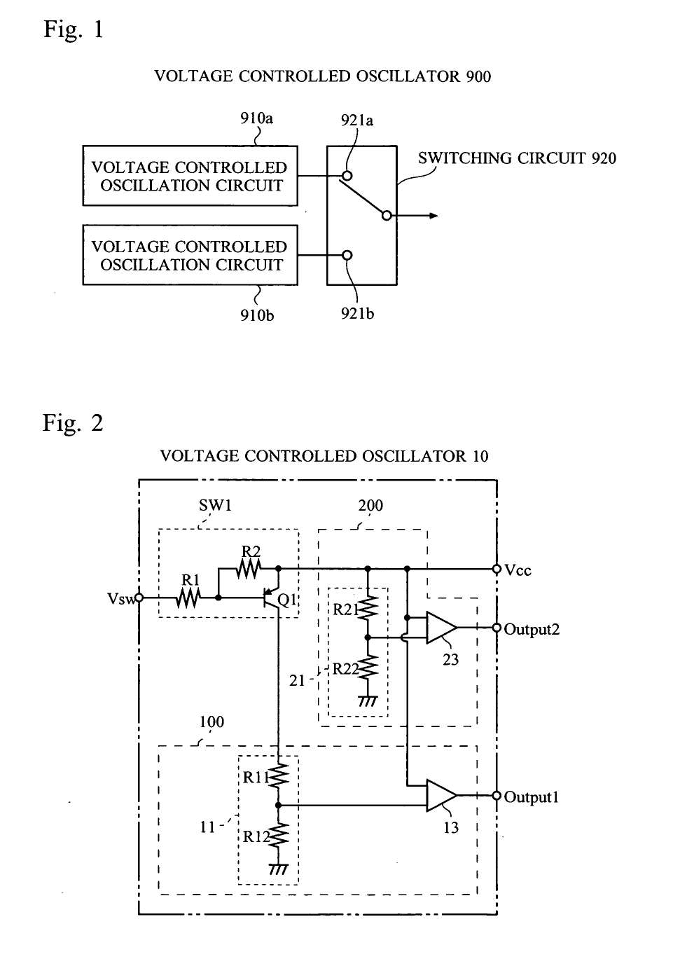

### DESCRIPTION OF THE PREFERRED EMBODIMENTS

The following is a description of embodiments of the present invention, with reference to the accompanying drawings.

A description will first be given, with reference to FIG. 2, of a first reference example in order to facilitate better understanding of embodiments of the present invention. A voltage controlled oscillator 10 of the first reference example is a dual-band voltage controlled oscillator capable of selectively outputting two different frequencies.

Referring to FIG. 2, the voltage controlled oscillator 10 includes a switching circuit SW1 and two voltage controlled oscillation circuits (a first voltage controlled oscillation circuit 100 and a second voltage controlled oscillation circuit 200). The first voltage controlled oscillation circuit 100 and the second voltage controlled oscillation circuit 200 operate in different frequency ranges.

In the above-mentioned circuitry, the switching circuit SW1 includes a PNP transistor Q1 and two resistors R1 and R2. A switching voltage V_{SW} is applied to the base of the PNP transistor Q1 through the resistor R1. A power supply voltage V_{CC} is applied to the emitter of the PNP transistor Q1. The power supply voltage V_{CC} is also applied to the base of the PNP transistor through the resistor R2.

The switching circuit SW1 switches a collector output (High/Low) depending on the switching voltage V_{SW}. Thus, the collector output switches the operations of circuits that follow the resistors R11 and R12.

The first voltage controlled oscillation circuit 100 includes a first bias circuit 11 and an amplifier 13 having a resonator therein. The first bias circuit 11 includes the resistors R11 and R12, which are connected in series. The other side of the resistor R11, which is not connected to the resistor R12, is connected to the collector of the PNP transistor Q1 in the switching circuit SW1. That is, the collector output of the PNP transistor Q1 is applied to the first bias circuit 11. The opposite side of the resistor R12, which is not connected to the resistor R11, is grounded.

In the first bias circuit 11, a point at which the resistor R11 and the resistor R12 are connected is also connected to an inverting input terminal of the amplifier 13. That is, the output voltage of the first bias circuit 11 is applied to the inverting input terminal of the amplifier 13. The power supply voltage V_{CC} is applied to the noninverting input terminal of the amplifier 13. The amplifier 13 oscillates at a frequency based on the difference in potential between the power supply voltage V_{CC} and the first bias circuit 11, and outputs the frequency as an Output 1.

Similarly, the second voltage controlled oscillation circuit 200 includes a second bias circuit 21 and an amplifier 23 having a resonator therein. The second bias circuit 21 includes the resistors R21 and R22, which are connected in series. The power supply voltage V_{CC} is applied to the other side of the resistor R21, which is not connected to the resistor R22. The opposite side of the resistor R22, which is not connected to the resistor R21, is grounded.

In the second bias circuit 21, a point at which the resistor R21 and the resistor R22 are connected is also connected to an inverting input terminal of the amplifier 23. That is, the output voltage of the second bias circuit 21 is applied to the inverting input terminal of the amplifier 23. The power supply voltage V_{CC} is applied to the noninverting input terminal of the amplifier 23. The amplifier 23 oscillates at a frequency based on the difference in potential between the power supply voltage V_{CC} and the second bias circuit 21, and outputs the frequency as an Output 2.

In the above-mentioned configuration, in the case where the switching voltage V_{SW} is low, the PNP transistor Q1 in the switching circuit SW1 is turned on, and the collector output of the PNP transistor Q1 is then supplied to the first bias circuit 11, so that the first voltage controlled oscillation circuit 100 having the resistor R11 operates. In contrast, in the case where the switching voltage V_{SW} is high, the PNP transistor Q1 in the switching circuit SW1 is turned off, and the voltage is not supplied to the first bias circuit 11, so that the first voltage controlled oscillation circuit 100 does not operate.

In the cases mentioned above, the second voltage controlled oscillation circuit 200 is always working. However, it is possible to control enabled/disabled state of the second voltage controlled oscillation circuit 200 by adjusting the ratio of resistance values of the resistors R11 and R21. In other words, by adjusting the ratio of resistance values of the resistor R11 in the first bias circuit 11 and the resistor R21 in the second bias circuit 21, it is possible to keep the second voltage controlled oscillation circuit 200 unoperated or disabled, while the first voltage controlled oscillation circuit 100 is operating. More specifically, the voltage controlled oscillator 10 allows only one of the voltage controlled oscillation circuits to operate.

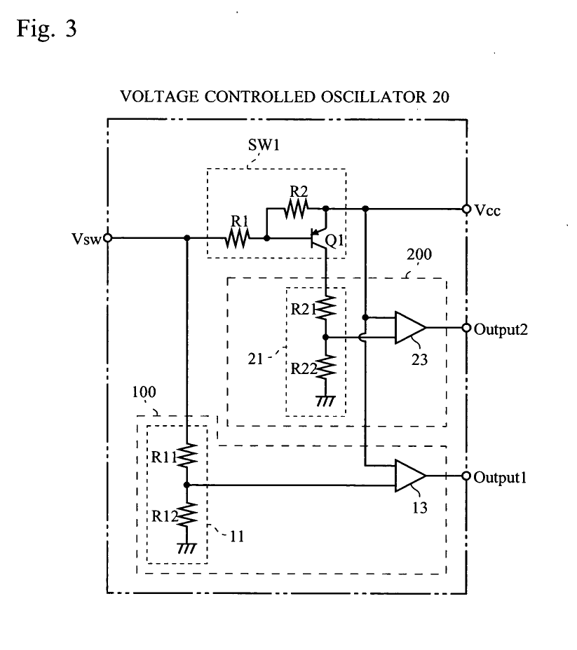

Next, a description will now be given of a second reference example, with reference to FIG. 3. FIG. 3 shows a voltage controlled oscillator 20. Hereinafter, in the second reference example, the same components and configurations as those of the first reference example have the same reference numerals and a detailed explanation will be omitted, if not otherwise specified.

Referring to FIG. 3, although the voltage controlled oscillator 20 has the same components as the voltage controlled oscillator 10, one end of the resistor R11 in the first bias circuit 11 (while the opposite end is connected to the resistor R12) is connected to an input terminal of the switching voltage V_{SW}, instead of being connected to the collector of the PNP transistor Q1 in the switching circuit SW1. That is, in the second reference example, the voltage controlled oscillator 20 is configured so that the switching voltage V_{SW} can be applied to the switching circuit SW1 and the first bias circuit 11. Also, one end of the resistor R21 in the second bias circuit 21 (while the opposite end is connected to the resistor R22) is connected to the collector of the PNP transistor Q1. The voltage controlled oscillator 20 is configured so that the output of the switching circuit SW1 can be applied to the second bias circuit 21. The other components are the same as those of the voltage controlled oscillator 10.

In the above-mentioned configuration, in the case where the switching voltage V_{SW} is low, no voltage is supplied to the first bias circuit, so that the first voltage controlled oscillation circuit 100 does not operate. In the switching circuit SW1, the PNP transistor Q1 is turned on, and the collector output of the PNP transistor Q1 is then supplied to the second bias circuit 21, so that the second voltage controlled oscillation circuit 200 operates. In contrast, in the case where the switching voltage V_{SW} is high, a voltage is supplied to the first bias circuit 11, which operates the first voltage controlled oscillation circuit 100. In the switching circuit SW1, the PNP transistor Q1 is turned off, no voltage is supplied to the second bias circuit 21, so that the second voltage controlled oscillation circuit 200 does not operate.

However, in the above-mentioned voltage controlled oscillator 10, in the case where the switching voltage V_{SW} is low, it is necessary to adjust the ratio of the resistance values of the resistor R11 in the first bias circuit 11 and the resistor R21 in the second bias circuit 21 in order to prevent the first voltage controlled oscillation circuit 100 and the second voltage controlled oscillation circuit 200 from simultaneously operating. It is thus impossible to control power consumption of the voltage controlled oscillation circuits 100 and 200 separately.

In addition, the above-mentioned voltage controlled oscillator 20 has a disadvantage in that, when the switching voltage V_{SW} is high, a relatively large amount of current flows in the input terminal of the switching voltage V_{SW}. Consequently, larger noises are generated from the first voltage controlled oscillation circuit 100, and may affect peripheral devices that control the switching voltage V_{SW}.

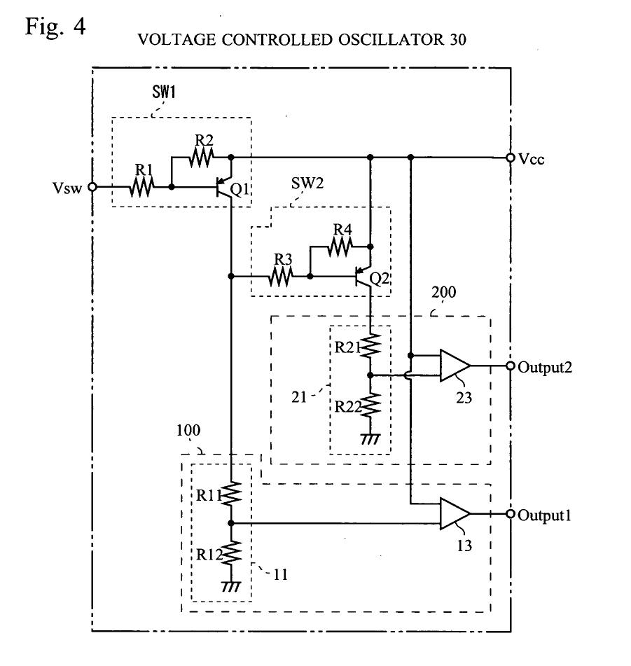

FIG. 4 shows a voltage controlled oscillator 30, according to an embodiment of the present invention. The voltage controlled oscillator 30 is configured to solve the above-mentioned problems. Hereinafter, in FIG. 4, the same components and configurations as those in the FIGS. 2 and 3 have the same reference numerals and a detailed explanation will be omitted, if not otherwise specified.

Referring to FIG. 4, the voltage controlled oscillator 30, which may have a single package, includes two switching circuits SW1 and SW2 and two voltage controlled oscillation circuits, namely, a first voltage controlled oscillation circuit 100 and a second voltage controlled oscillation circuit 200.

The switching circuit SW1, which serves as a first switching circuit, includes a PNP transistor Q1. The switching voltage V_{SW} is applied to the base of the PNP transistor Q1 through a resistor R1. A power supply voltage V_{CC} is applied to the emitter of the PNP transistor Q1. The power supply voltage V_{CC} is also applied to the base of the PNP transistor Q1 through R2. Therefore, the collector output of the PNP transistor Q1, which serves as a first PNP transistor, is switched according to the switching voltage V_{SW} applied to the base.

The switching circuit SW2, which serves as a second switching circuit, has the same circuitry as the switching circuit SW1. However, the collector output of the PNP transistor Q1 is applied to the base of the PNP transistor Q2 through a resistor R3. The transistor Q2, which serves as a second PNP transistor, corresponds to the transistor Q1 in the switching circuit SW1. The resistor R3 corresponds R1 in the switching circuit SW1. The power supply voltage V_{CC} is also applied to the base of the PNP transistor Q2 through a resistor R4. The resistor R4 corresponds to R2 in the SW1. Therefore, the collector output of the PNP transistor Q2 is switched opposite to the collector output of the PNP transistor Q1.

In the first voltage controlled oscillation circuit 100, the collector output of the PNP transistor Q1 in the switching circuit SW1 is applied to the first bias circuit 11. Similarly, in the second voltage controlled oscillation circuit 200, the collector output of the PNP transistor Q2 in the switching circuit SW2 is applied to the second bias circuit 21.

In the above-mentioned configuration, the switching circuit SW1 enables and disables the circuit connected to the collector of the PNP transistor Q1. That is, the first voltage controlled oscillation circuit 100 is switched to the selected state or unselected state. Similarly, the second switching circuit SW2 enables and disables the circuit connected to the collector of the PNP transistor Q2. That is, the second voltage controlled oscillation circuit 200 is switched to the selected state or unselected state.

In the case where the switching voltage V_{SW} is low, the PNP transistor Q1 is turned on, and the resultant voltage is supplied to the first voltage controlled oscillation circuit 100 having the resistor R11. In this case, the PNP transistor Q2 is turned off, and no voltage is supplied to the second voltage controlled oscillation circuit 200 having the resistor R21. In contrast, in the case where the switching voltage V_{SW} is high, the PNP transistor Q1 is turned off, and no voltage is supplied to the first voltage controlled oscillation circuit 100 having the resistor R11. In this case, the PNP transistor Q2 is turned on, and the resultant voltage is supplied to the second voltage controlled oscillation circuit 200 having the resistor R21.

As described above, the voltage controlled oscillator 30 includes the two voltage controlled oscillation circuits 100 and 200 and the pair of PNP transistors Q1 and Q2. These transistors switch the bias circuits 11 and 12. It is thus possible to completely cut off the collector output to the circuit switched to the disabled state and to totally shut down the disabled circuit. As a result of the above switching control, power consumed in each voltage controlled oscillation circuit can be controlled separately.

The switching voltage V_{SW} is connected to the bias circuits 11 and 21 respectively through the PNP transistors Q1 and Q2. It is possible to prevent a large amount of current flowing into the input terminal to which the switching voltage V_{SW} is applied. This makes it possible to reduce the affect made on the peripheral devices due to noise or the like.

The present invention is not limited to the specifically disclosed embodiments, and other embodiments, variations and modifications may be made without departing from the scope of the present invention.

The present invention is based on Japanese Patent Application No. 2003-341873 filed on Sep. 30, 2003, the entire disclosure of which is hereby incorporated by reference.

1. A switching circuit comprising:
a first PNP transistor having a collector output switched on and off based on a switching voltage applied to a base; and
a second PNP transistor having a collector output opposite to the collector output of the first PNP transistor,
first and second circuits respectively coupled with the first and second PNP transistors being selectively operated in accordance with the collector outputs of the first and second PNP transistors.

2. A voltage controlled oscillator comprising:
a first voltage controlled oscillation circuit;
a second voltage controlled oscillation circuit; and
a switch selectively operates the first and second voltage controlled oscillation circuits,
wherein:
the switch includes a first PNP transistor having a collector output switched on and off based on a switching voltage applied to a base, and a second PNP transistor having a collector output opposite to the collector output of the first PNP transistor; and
the first and second voltage controlled oscillation circuits are selectively operated in accordance with the collector outputs of the first and second PNP transistors.

3. The voltage controlled oscillator as claimed in claim 2, wherein:
the first voltage controlled oscillation circuit includes a first bias circuit;
the second voltage controlled oscillation circuit includes a second bias circuit;
the collector output of the first PNP transistor is connected to the first bias circuit; and
the collector output of the second PNP transistor is connected to the second bias circuit.

4. The voltage controlled oscillator as claimed in claim 2, wherein the voltage controlled oscillator is incorporated into a single package.

5. A voltage controlled oscillator comprising:
two voltage controlled oscillation circuits that respectively oscillate in two different frequency ranges; and
a switching circuit that selects one of the two voltage controlled oscillation circuits,
wherein the switching circuit includes two PNP transistors respectively associated with the two voltage controlled oscillation circuits.

6. The voltage controlled oscillator as claimed in claim 5, wherein:
the two voltage controlled oscillation circuits respectively include bias circuits; and
the switching circuit selects one of the bias circuits to which a voltage should be supplied.

7. The voltage controlled oscillator as claimed in claim 5, wherein the voltage controlled oscillator is incorporated into a single package.
